(19) United States
(12) Patent Application Publication
(10) Pub. No.: US 2026/0014934 A1
(43) Pub. Date: Jan. 15, 2026

(54) MICRO-LED DISPLAY

(71) Applicant: Gentex Corporation, Zeeland, MI (US)

(72) Inventors: Andrew D. Weller, Holland, MI (US); Bradley A. Bosma, Hudsonville, MI (US); David Falb, Grand Rapids, MI (US)

(73) Assignee: Gentex Corporation, Zeeland, MI (US)

(21) Appl. No.: 19/262,596

(22) Filed: Jul. 8, 2025

Related U.S. Application Data
(60) Provisional application No. 63/669,307, filed on Jul. 10, 2024.

(51) Int. Cl. B60R 1/26; B60R 1/08; B60R 1/12; B60R 1/30; G09G 3/32; H10H 29/24

(52) U.S. Cl. CPC B60R 1/26; B60R 1/088; B60R 1/12; B60R 1/30; G09G 3/32; H10H 29/24; B60R 2001/1223; B60R 2001/1253; B60R 2300/103; G09G 2330/021; G09G 2330/045; G09G 2354/00; G09G 2360/145; G09G 2380/10

(57) ABSTRACT

A rearview mirror assembly includes a housing, a camera, and a display coupled to the housing. The display includes a backplane connected to a plurality of chiplets that include an array of micro-LEDs. At least one of an infrared emitter configured to project light in the infrared spectrum and a sensor are coupled to and in operable communication with at least one of the chiplets. The sensor is selected from a group comprising a light sensing module configured to detect light in the visible spectrum, an infrared sensing module configured to detect light in the infrared spectrum, and a temperature sensor configured to detect a temperature proximate the temperature sensor.

### CROSS-REFERENCE TO RELATED APPLICATION

This application claims priority to and the benefit under 35 U.S.C. § 119 (e) of U.S. Provisional Application No. 63/669,307, filed on Jul. 10, 2024, entitled “MICRO-LED DISPLAY,” the disclosure of which is hereby incorporated herein by reference in its entirety.

### FIELD OF THE DISCLOSURE

The present disclosure generally relates to a rearview mirror assembly with a micro-LED display.

### SUMMARY OF THE DISCLOSURE

According to an aspect of the present disclosure, a rearview mirror assembly includes a housing, a camera, and a display coupled to the housing. The display includes a backplane connected to a plurality of chiplets that include an array of micro-LEDs. At least one of an infrared emitter configured to project light in the infrared spectrum and a sensor are coupled to and in operable communication with at least one of the chiplets. The sensor is selected from a group comprising a light sensing module configured to detect light in the visible spectrum, an infrared sensing module configured to detect light in the infrared spectrum, and a temperature sensor configured to detect a temperature proximate the temperature sensor.

According to another aspect, a rearview mirror assembly includes a housing and a display coupled to the housing. The display includes a backplane connected to a plurality of chiplets that each include an array of micro-LEDs. The chiplets include internal sensors. A control system is configured to compare data associated with an image requested with data associated with an image produced on the display, and, if the image produced is not substantially the same as the image requested, take a corrective action.

According to still yet another aspect of the present disclosure, a rearview mirror assembly includes a housing and a display coupled to the housing that includes a backplane connected to a plurality of chiplets. An array of micro-LEDs are coupled to at least some of the plurality of chiplets. At least one of an emitter and a sensor are coupled to at least some of the plurality of chiplets.

According to various aspects of the present disclosure, a rearview mirror assembly includes a display that utilizes micro-LEDs. In micro-LED displays, the micro-LEDs used to create viewable pixels are substantially smaller than traditional LED and LCD technologies and therefore provide substantially more space that can be utilized within the display (e.g., a backplane that the micro-LEDs are coupled to). According to certain aspects of the disclosure, this additional space is utilized for additional electronic components with different types of functionalities, such as sensors, emitters, and/or the like. In some implementations, one, more, or each of the micro-LEDs, the sensors, and/or the emitters are operably coupled and packaged on chiplets.

These and other features, advantages, and objects of the present disclosure will be further understood and appreciated by those skilled in the art by reference to the following specification, claims, and appended drawings.

### BRIEF DESCRIPTION OF THE DRAWINGS

In the drawings:

FIG. 1 is a front elevational view of a rearview mirror assembly with a display including a micro-LED configuration, according to an aspect of the present disclosure;

FIG. 2A is a cross-sectional view of a portion of a rearview mirror assembly including a micro-LED configuration, according to an aspect of the present disclosure;

FIG. 2B is an enlarged cross-sectional view of a portion of a rearview mirror assembly including a micro-LED configuration of a first configuration, according to an aspect of the present disclosure;

FIG. 2C is an enlarged cross-sectional view of a portion of a rearview mirror assembly including a micro-LED configuration of a second configuration, according to an aspect of the present disclosure; and

FIG. 3 is a partially schematic front surface of a rearview mirror assembly with a display including a micro-LED configuration, according to an aspect of the present disclosure.

### DETAILED DESCRIPTION

The present illustrated embodiments reside primarily in combinations of method steps and apparatus components related to review mirror assembly with a micro-LED display. Accordingly, the apparatus components and method steps have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein. Further, like numerals in the description and drawings represent like elements.

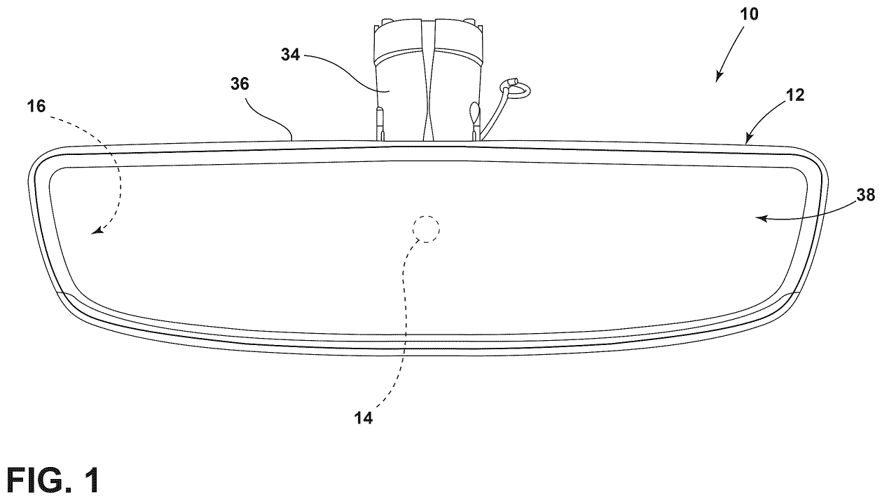

For purposes of description herein, the terms “upper,” “lower,” “right,” “left,” “rear,” “front,” “vertical,” “horizontal,” and derivatives thereof, shall relate to the disclosure as oriented in FIG. 1. Unless stated otherwise, the term “front” shall refer to the surface of the device closer to an intended viewer of the device, and the term “rear” shall refer to the surface of the device further from the intended viewer of the device. However, it is to be understood that the disclosure may assume various alternative orientations, except where expressly specified to the contrary. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

The terms “including,” “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises a . . . ” does not, without more constraints, preclude the existence of additional identical elements in the process, method, article, or apparatus that comprises the element.

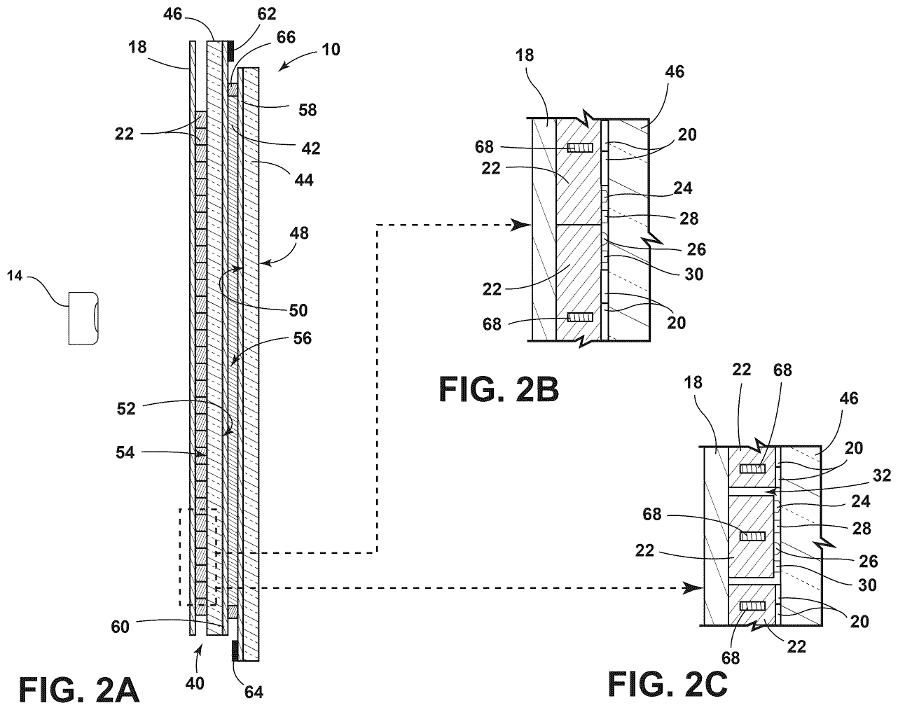

Referring initially to FIGS. 1-2C, reference numeral 10 generally designates a rearview mirror assembly. The rearview mirror assembly 10 may include a housing 12, a camera 14, and a display 16 coupled to the housing 12. The display 16 includes a printed circuit board (“backplane 18”) connected to a plurality of chiplets 22 that each include an array of micro-LEDs. At least one of an infrared emitter 24 configured to project light in the infrared spectrum and a sensor are coupled to and in operable communication with at least one of the chiplets 22. The sensor is selected from a group comprising a light sensing module 26 configured to detect light in the visible spectrum, an infrared sensing module 28 configured to detect light in the infrared spectrum, and a temperature sensor 30 configured to detect a temperature proximate the temperature sensor 30.

With continued reference to FIGS. 1-2B, the arrays of micro-LEDs 20 may each be located on different ones of the plurality of different chiplets 22, the plurality of chiplets 22 may be in operable communication with a control system 100. In this manner, the control system 100 may be configured to receive information from each of the chiplets 22 associated with the performance of the micro-LEDs 20, the infrared emitter 24, and/or the sensor(s) and take a corrective action if the information indicates improper performance. As will be detailed in reference to FIG. 2C, in other embodiments, spaces 32 may be defined between the chiplets 22 associated with an array of micro-LEDs 20, and the infrared emitter 24 and sensor(s) may be located within the spaces 32 directly coupled to the backplane 18 or, alternatively, on discrete chiplets 22 that do not include the array of micro-LEDs 20. The location of the chiplets 22 and the micro-LEDs 20 are depicted in FIGS. 2A and 2B. In some embodiments, each chiplet 22 may be connected to a single micro-LED 20 or a plurality of micro-LEDs 20. In some embodiments, each chiplet 22 may be connected to one or more micro-LEDs 20 and one or both of the infrared emitters 24 and sensors described herein. Accordingly, the chiplets 22 may permit a performance review of the micro-LEDs 20 in addition to functionalities related to one, more, or each of the infrared emitter 24, the light sensing module 26, the infrared sensing module 28, and/or the temperature sensor 30.

Generally speaking, the chiplets 22 may be a silicon or glass device with isolated traces for providing energy to select ones of the micro-LEDs 20 and/or other components associated with the chiplets 22 (e.g., one or both of the infrared emitters 24 and sensors described herein). Rather than requiring the micro-LEDs to be positioned on the backplane 18 individually, the chiplets 22 allow a single or array of micro-LEDs 20 (e.g., 3×3, 4×4, or more micro-LEDs 20) in addition to the infrared emitter 24 and/or sensor(s) to be quickly installed to ease assembly and accuracy in mass production. The micro-LEDs 20 may be patterned in arrays on one or more chiplets 22, each array may include micro-LEDs of different colors (e.g., red, green, blue, white). The individual intensities of the different colored micro-LEDs 20 in the array can be precisely controlled to obtain a range of colors across the visible spectrum. The control system 100 may send instructions to the micro-LEDs 20, the infrared emitter 24, and/or the sensor(s) through the chiplets 22. In some embodiments, the chiplets 22 include additional control circuitry for controlling the micro-LEDs 20, the infrared emitter 24, and/or the sensor(s) globally and/or individually.

The backplane 18 may be configured as a glass or an otherwise visibly transparent substrate that contains traces routed to and in operable communication with the chiplets 22 (e.g., each micro-LED 20). In some embodiments, the traces are also routed to and in operable communication with some or all of the infrared emitters 24, the light sensing module 26, the infrared sensing module 28, and/or the temperature sensor 30, if present. In some embodiments, the backplane 18 may include, for example, transistors in operable communication with the traces and function as an active backplane 18. In some embodiments, the backplane 18 may not include transistors in operable communication with the traces and function as a passive backplane 18. The traces may, for example, be an indium tin oxide (“ITO”) coated on the backplane 18 in a pattern. However, it should be appreciated that the traces may be formed of other conductive materials, such as fluorine-doped tin oxide, doped zinc oxide, indium zinc oxide (Zn3In2O6), ITO/metal/ITO (IMI), and/or other types of transparent or semi-transparent conductive materials. The control system 100 and/or components therefore may be located on a larger network chip (e.g., a primary PCB). The larger network chip may be located on, for example, the backplane 18 (e.g., a rear surface of the backplane 18) a PCB, or other locations for operable communication with the traces.

With reference now to FIG. 1, the rearview mirror assembly 10 may include a mounting member 34 for mounting to an upper region of a vehicle cabin. For example, the mounting member 34 may be configured to mount to a front window and/or overhead region above the front window. The housing 12 may define a bezel 36 that defines a viewing surface 38. The display 16 encompasses a majority (e.g., substantially all) of the viewing surface 38. In operation, the camera 14 may capture image data (e.g., pictures, videos, etc.) within an interior and/or exterior of the vehicle that can be displayed on the display 16. However, the display 16 may also generate other types of images, videos, or graphics not captured by the camera 14. In some implementations, the camera 14 may be coupled to and located within the housing 12 (e.g., behind the display 16) and configured to capture the image data through the display 16.

With reference now to FIGS. 2A, the display 16 may be part of an optical stack that may include an electro-optic assembly 40 coupled to the housing 12 and configured to switch transmission states upon an applied voltage. While the electro-optic assembly 40 is depicted as located between the display 16 and the viewing surface 38, it should be appreciated that the display 16 may alternatively be located between the electro-optic assembly 40 and the viewing surface 38. The electro-optic assembly 40 may include an electro-optic medium 42 located between a pair of substrates. The pair of substrates may include a front substrate 44 as well as a rear substrate 46. The front substrate 44 may include a first surface 48 and a second surface 50 and the rear substrate 46 may include a third surface 52 and a fourth surface 54. The second surface 50 and the third surface 52 may face each other to define a cavity 56 for holding the electro-optic medium 42. In some embodiments, the viewing surface 38 is the same and/or defined by the first surface 48. A first electrode 58 is coupled to the second surface 50, and a second electrode 60 is coupled to the third surface 52. In some implementations, the electro-optic assembly 40 (e.g., the electro-optic medium 42) substantially covers the entire viewing surface 38.

With continued reference to FIG. 2A, the first electrode 58 and the second electrode 60 may be formed by electrically conductive transparent materials, including, but not limited to, a transparent conducting film (e.g., indium tin oxide (ITO), F:SnO2, ZnO, IZO), insulator/metal/insulator stack “IMI Structures”, carbon (graphene and/or graphite), and/or a conductive metal mesh (e.g., nanowires). In various examples, the electro-optic medium 42 may include at least one solvent, at least one anodic material, and at least one cathodic material. Typically, both of the anodic and cathodic materials are electroactive and at least one of them may be electrochromic. It will be understood that regardless of its ordinary meaning, the term “electroactive” may mean a material that undergoes a modification in its oxidation state upon exposure to a particular electrical potential difference. Additionally, it will be understood that the term “electrochromic” may mean, regardless of its ordinary meaning, a material that exhibits a change in its extinction coefficient at one or more wavelengths upon exposure to a particular electrical potential difference.

A first electrical bus 62 may be coupled to (i.e., in conductive communication with) the first electrode 58 and a second electrical bus 64 may be connected to the second electrode 60. The electric buses 62, 64 may include a conductive adhesive, tape, and/or the like, that may include a higher electric conductivity than one of or both of the first electrode 58 and the second electrode 60. In this manner, the electrical buses 62, 64 may provide current to the electrodes 58, 60. The electric buses 62, 64 may be placed on an internal surface (e.g., a surface that faces towards the cavity 56) of the first electrode 58 and/or the second electrode 60, or the buses 62, 64 may be placed on an outer surface (e.g., a surface that faces away from the cavity 56) of the first electrode 58 and/or the second electrode 60. In some instances, the buses 62, 64 may traverse an entire perimeter of the cavity 56 or may be localized to one or more discrete locations. One or more seals 66 may confine the electro-optic medium 42 in the cavity 56.

As depicted in FIG. 2B, the chiplets 22 connected to the micro-LED's 20 may include regions that are free of the micro-LED's 20 for connection to one or more of the infrared emitter 24, the light sensing module 26, the infrared sensing module 28, and/or the temperature sensor 30. In some embodiments, some chiplets 22 include some of the infrared emitter 24, the light sensing module 26, the infrared sensing module 28, and/or the temperature sensor 30 and other chiplets 22 include other ones of the infrared emitter 24, the light sensing module 26, the infrared sensing module 28, and/or the temperature sensor 30. The chiplets 22 may include internal sensors 68 or control chips that detect and communicate what is being transmitted to the micro-LEDs 20. The internal sensor 68 may also be in operable communication with one or more of the infrared emitter 24, the light sensing module 26, the infrared sensing module 28, and/or the temperature sensor 30. In this manner, the control system 100 may be configured to inquire and/or otherwise monitor the internal sensors 68 to confirm that an image produced on the display 16 is substantially the same as an image requested (e.g., by the control system 100) to the display 16. Therefore, the control system 100 may be configured to compare data associated with the image requested with data associated with the image produced and determine if the image produced is substantially the same as the image requested. If the image produced is not substantially the same as the image requested, the control system 100 may be configured to take corrective action (e.g., restart), generate information to a user that the produced image is inaccurate and should not be relied upon, otherwise request servicing, and/or the like. Likewise, the control system 100 (e.g., via communication with internal sensor 68) may be configured to monitor, detect problems, and improve performance and accuracy of the associated ones of the infrared emitter 24, the light sensing module 26, the infrared sensing module 28, and the temperature sensor 30.

As best depicted in FIG. 2C, in some embodiments, if present, the spaces 32 between at least some of the plurality of micro-LEDs 20 (e.g., the spaces 32 between chiplets 22) may include each or select ones of the infrared emitter 24, the light sensing module 26, the infrared sensing module 28, and the temperature sensor 30. In some embodiments, some spaces 32 include some of the infrared emitter 24, the light sensing module 26, the infrared sensing module 28, and/or the temperature sensor 30 and other spaces 32 include other ones of the of the infrared emitter 24, the light sensing module 26, the infrared sensing module 28, and/or the temperature sensor 30. In some embodiments, the infrared emitter 24, the light sensing module 26, the infrared sensing module 28, and/or the temperature sensor 30 that are located in the spaces 32 are in operable communication with the control system 100 through the backplane 18 and/or otherwise connected to the backplane 18.

With continued reference to FIG. 2C, in some embodiments, each or select ones of the infrared emitter 24, the light sensing module 26, the infrared sensing module 28, and the temperature sensor 30 may also be coupled to chiplets 22 that are different than the chiplets 22 connected to the micro-LEDs 20. The discrete chiplets 22 associated with each or select ones of the infrared emitter 24, the light sensing module 26, the infrared sensing module 28, and the temperature sensor 30 may also include the sensor 68. In this manner, the control system 100 may be configured to monitor, detect problems, and improve the performance and accuracy of the associated ones of the infrared emitter 24, the light sensing module 26, the infrared sensing module 28, and the temperature sensor 30.

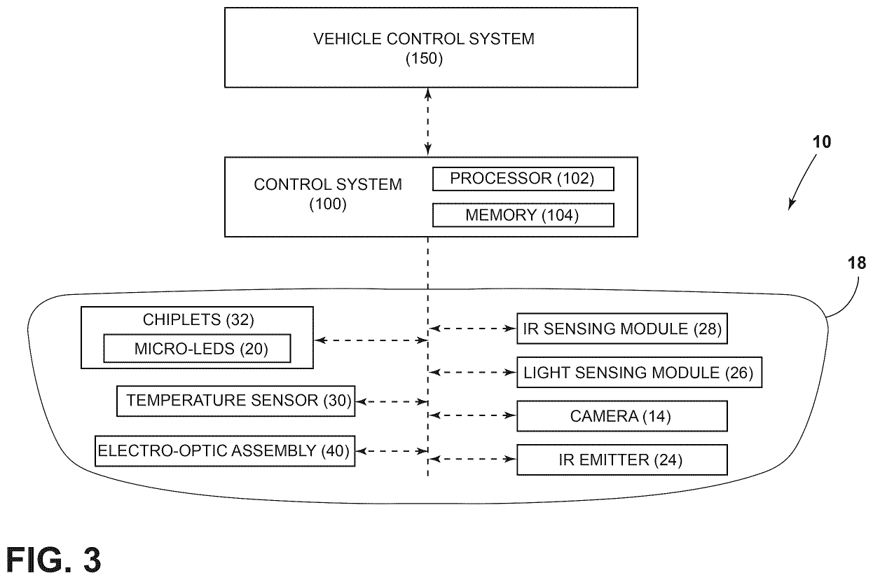

With reference now to FIGS. 2B through 3, the control system 100 may include a processor 102 and a memory 104. In some embodiments, the control system 100 and/or components thereof are located on the backplane 18 and/or otherwise in operable communication with the backplane 18 and components associated therewith. The processor 102 may include any suitable processor 102 or any suitable number of processors, in addition to or other than the processor 102. The memory 104 may comprise a single disk or a plurality of disks (e.g., hard drives) and includes a storage management module that manages one or more partitions within the memory 104. In some embodiments, memory 104 may include flash memory, semiconductor (solid state) memory, or the like. The memory 104 may include Random Access Memory (RAM), a Read-Only Memory (ROM), Electrically Erasable Programmable Read-Only Memory (EEPROM), or a combination thereof. The memory 104 may include instructions that, when executed by the processor 102, cause the processor 102 to, at least, perform the functions associated with the components of the rearview mirror assembly 10. The camera 14, the display 16, the plurality of micro-LEDs 20 (e.g., the chiplets 22), the infrared emitter 24, the light sensing module 26, the infrared sensing module 28, the temperature sensor 30, and/or the electro-optic assembly 40, may, therefore, be controlled by, receive signals, and/or transmit signals to the control system 100.

Referring still to FIGS. 2B through 3, in some embodiments, the control system 100 may be configured to, in addition to controlling the output (e.g., image generation) of the display 16, may further perform functionalities related to the infrared emitter 24, the light sensing module 26, the infrared sensing module 28, and/or the temperature sensor 30. For example, in some embodiments, the infrared emitter 24 and the infrared sensing module 28 may, in conjunction, operate as a human-machine interface. More particularly, the plurality of the infrared sensing modules 28 may be located proximate to different ones of the plurality of the infrared emitters 24. In operation, the plurality of infrared sensing modules 28 are configured to detect increases in the presence of light in the infrared spectrum that occur as a vehicle occupant moves a hand in close proximity to the infrared emitter 24, reflecting at least part of the infrared light back towards the infrared sensing modules 28. The control system 100 is configured to obtain the detected increases in the presence of the infrared spectrum of light from the plurality of infrared sensing modules 28 and generate a user input associated with the region (e.g., one or more chiplets 22 associated with the infrared sensing modules 28) of the detected increases in the presence of the infrared spectrum of light. For example, different regions associated with the viewing surface 38 may correspond to different user inputs. In some embodiments, once the infrared sensing modules 28 detect user interaction, the control system 100 is configured to generate a user menu with the display 16, providing user options in various regions of the viewing surface 38. The user options generated may be textual and relate to various features of the rearview mirror assembly 10 and/or a vehicle control system 150 that may be in operable communication with the control system 100. For example, the user options may include options to generate a global positioning system (“GPS”) map, generate images from image data captured by the camera 14, select between multiple interior and/or exterior cameras (e.g., RGB cameras in addition to camera 14) for different field-of-views and/or the like. In some implementations, the user options may include options to accept calls, adjust seats, adjust audio settings, operate interior lights, temperature settings, open garage doors, and/or the like.

With continued reference still to FIGS. 2B through 3, the camera 14 may be configured to capture infrared light from the infrared emitters 24. The infrared emitters 24 may therefore be configured to generate flood illumination in the infrared spectrum and/or patterned illumination in the infrared spectrum. In this manner, the infrared emitters 24 may be configured a lasers, flood emitters, and/or a combination of laser emitters and flood emitters. When laser emitters and flood emitters are utilized, the flood emitters and laser emitters may be sequenced to not generate light at the same time. In some embodiments, the control system 100 may be configured to obtain the image data and detect a position of a vehicle occupant and other driver monitoring functionalities. For example, the plurality of infrared emitters 24 may be configured to project light (e.g., via laser emitters) in the infrared spectrum in a pattern (e.g., with a plurality of light spots) and the control system 100 may be configured to extrapolate the position of the vehicle occupant in three-dimensional (“3D”) space based on changes to the pattern for additional driver monitoring functionalities. The driver monitoring functionalities may include monitoring the health of the driver, attention of the driver, positions and statuses of occupants of the vehicle, driver identity confirmation (e.g., biometrics), and/or the like. In some implementations, the control system 100 (e.g., via the image data captured by camera 14) may be configured to monitor individual light spots or pixels associated therewith to detect changes in the speckle pattern that may be associated with movements on the micrometer or microradian scale. Such implementations may be beneficial for monitoring the health of the driver or occupants via the detection of small movements/vibrations that may be related to, for example, an occupant's heartbeat and breathing.

Referring still to FIGS. 2B through 3, the light sensing module 26 is configured to detect light in the visible spectrum. In this manner, the light sensing modules 26 may detect the presence or likelihood of glare on the viewing surface 38. The control system 100 may, therefore, be configured to apply a voltage differential to reduce transmission of the electro-optic assembly 40 and lower the presence of the detected light. In some embodiments, the electro-optic assembly 40 may include a plurality of conductively isolated segmentations. In this manner, the control system 100 may be configured to apply the voltage and reduce transmission of select segmentations of electro-optic assembly 40 associated with the detected light. In some embodiments, the light sensing module 26 may also be configured to detect a brightness from the micro-LEDs 20. The detected brightness of the micro-LEDs 20 may, for example, be utilized by the control system 100 to control brightness locally or globally across the display 16. In some embodiments, the light sensing module 26 may detect ambient lighting and the control system 100 may adjust to the brightness of the micro-LEDs 20 based on the levels of ambient lighting. For example, the control system 100 may be configured to reduce the brightness of the micro-LEDs 20 when the ambient lighting decreases.

Referring still to FIGS. 2B through 3, the temperature sensor 30 is configured to detect a temperature proximate the temperature sensor 30. By receiving the detected temperature proximate the temperature sensor 30, the control system 100 may be further configured to reduce power to the display 16 and regulate the temperature proximate the temperature sensor 30. In this manner, the control system 100 can prevent overheating of the display 16 and provide longevity to the operational life of the display 16. The reduction of power may refer to decreasing the contrast, brightness, saturation, and/or the like. Because the control system 100 may be in operable communication with the vehicle control system 150, the control system 100 may compare temperature proximate the temperature sensor 30 to temperature settings or temperature detections from the vehicle control system 150.

The incorporation of the micro-LEDs 20, the chiplets 22, and the free spaces 32 that can incorporate one, more, or each of the infrared emitter 24, and/or the sensor(s) permit the control system 100 to receive information from each of the chiplets 22 associated with performance. For example, once a request for generating an image or graphic on the display 16 is initiated, the settings of the individual intensities of the different colored micro-LEDs 20 may be requested and monitored by the control system 100 via communication with the chiplets 22 (e.g., the internal sensors 68). More particularly, once the image or graphic is generated, the control system 100 may monitor and compare the color, intensity, hue, or other properties of the micro-LEDs 20 to ensure that they match the initial request. In some implementations, the light sensing module 26 may be utilized in monitoring the output of the micro-LEDs 20. When the settings or output of the micro-LEDs 20 do not match the initial request, the control system 100 may take the afore-described corrective action. In further implementations, the control system 100 may receive information from chiplets 22 associated with the infrared emitter 24 settings, the light sensing module 26 detections, the infrared sensing module 28 detections, and the temperature sensor 30 detections. For example, if an increase in the presence of infrared light is detected with some (e.g., a majority within a region) but not all of a plurality of proximate infrared sensing modules 28, the control system 100 may determine that the one or infrared sensing module(s) 28 is inoperable. In response, the control system 100 may take the afore-described corrective action. Similarly, if select ones (e.g., a minority within a region) of the infrared sensing modules 28 detect a higher presence of infrared light, the control system 100 may determine that the reading are incorrect and take a corrective action. When it relates specifically to the various sensors described herein, it should be appreciated that the corrective action may include filtering out or averaging detected quantities (e.g., via communication with the chiplets 22).

The disclosure herein is further summarized in the following paragraphs and is further characterized by combinations of any and all of the various aspects described therein.

According to one aspect of the present disclosure, a rearview mirror assembly includes a housing, a camera, and a display coupled to the housing. The display includes a backplane connected to a plurality of chiplets that include an array of micro-LEDs. At least one of an infrared emitter configured to project light in the infrared spectrum and a sensor are coupled to and in operable communication with at least one of the chiplets. The sensor is selected from a group comprising a light sensing module configured to detect light in the visible spectrum, an infrared sensing module configured to detect light in the infrared spectrum, and a temperature sensor configured to detect a temperature proximate the temperature sensor.

According to another aspect, a camera is coupled to a housing and located behind a display and configured to capture image data through the display.

According to yet another aspect, a rearview mirror assembly includes a plurality of the infrared emitters coupled to at least two or more of a plurality of chiplets.

According to still another aspect, a rearview mirror assembly includes a plurality of the infrared sensing modules coupled to at least two or more of a plurality of chiplets, the plurality of the infrared sensing modules located proximate different ones of a plurality of the infrared emitters.

According to another aspect, each of a plurality of infrared sensing modules is configured to detect increases in a presence of light in the infrared spectrum.

According to yet another aspect, a control system is configured to obtain the detected increases in the presence of the infrared spectrum of light from the plurality of infrared sensing modules and generate a user input associated with the region of the detected increases in the presence of the infrared spectrum of light.

According to still another aspect, a camera is configured to capture image data of a projected light in the infrared spectrum from a plurality of the infrared emitters.

According to yet another aspect, a control is system configured to obtain the image data and detect a position of a vehicle occupant.

According to still another aspect, a plurality of infrared emitters are configured to project light in the infrared spectrum in a pattern, and a control system is configured to extrapolate the position of the vehicle occupant in three-dimensional (“3D”) space based on changes to the pattern.

According to yet another aspect, a rearview mirror assembly includes a light sensing module configured to detect light in the visible spectrum, the light sensing module coupled to at least one of a plurality of chiplets.

According to still another aspect, a rearview mirror assembly includes an electro-optic assembly coupled to a housing and configured to switch transmission states upon an applied voltage.

According to another aspect, a control system is configured to apply a voltage differential to reduce transmission of the electro-optic assembly light based on the detected light from the light sensing module.

According to yet another aspect, a rearview mirror assembly includes a temperature sensor configured to detect a temperature proximate the temperature sensor, the temperature sensor is coupled to at least one of a plurality of chiplets.

According to still another aspect, a control system is configured to reduce power to a display based on the detected temperature and regulate the temperature proximate the temperature sensor.

According to yet another aspect, a plurality of chiplets are in operable communication with a control system.

According to still another aspect, the control system is configured to receive information from each of the chiplets associated with the performance of the arrays of micro-LEDs, and take a corrective action if the information indicates improper performance.

According to yet another aspect, an infrared emitter and a sensor are in operable communication with a control system through at least one of a plurality of chiplets.

According to another aspect of the present disclosure, a rearview mirror assembly includes a housing and a display coupled to the housing. The display includes a backplane connected to a plurality of chiplets that each include an array of micro-LEDs. The chiplets include internal sensors. A control system is configured to compare data associated with an image requested with data associated with an image produced on the display, and, if the image produced is not substantially the same as the image requested, take a corrective action.

According to another aspect, the array of micro-LEDs include red micro-LEDs, green micro-LEDs, and blue micro-LEDs and the control system is configured to compare an intensity of each micro-LEDs to the requested image.

According to yet another aspect, a rearview mirror assembly includes a plurality of light sensing modules that detect output of the micro-LEDs and the control system is further configured to compare the output of the micro-LEDs to the requested image.

According to still yet another aspect of the present disclosure, a rearview mirror assembly includes a housing and a display coupled to the housing that includes a backplane connected to a plurality of chiplets. An array of micro-LEDs are coupled to at least some of the plurality of chiplets. At least one of an emitter and a sensor are coupled to at least some of the plurality of chiplets.

According to another aspect, at least some of the chiplets coupled to the micro-LEDs are also coupled to at least one of the emitter and the sensor.

According to yet another aspect, the chiplets coupled to the micro-LEDs are different than the chiplets coupled to at least one of the emitter and the sensor.

It will be understood by one having ordinary skill in the art that construction of the described disclosure and other components is not limited to any specific material. Other exemplary embodiments of the disclosure disclosed herein may be formed from a wide variety of materials, unless described otherwise herein.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

It is also important to note that the construction and arrangement of the elements of the disclosure, as shown in the exemplary embodiments, is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts, or elements shown as multiple parts may be integrally formed, the operation of the interfaces may be reversed or otherwise varied, the length or width of the structures and/or members or connectors or other elements of the system may be varied, and the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present disclosure. The exemplary structures and processes disclosed herein are for illustrative purposes and are not to be construed as limiting.

It is also to be understood that variations and modifications can be made on the aforementioned structures and methods without departing from the concepts of the present disclosure, and further it is to be understood that such concepts are intended to be covered by the following claims unless these claims by their language expressly state otherwise.

What is claimed is:

1. A rearview mirror assembly, comprising:
a housing;
a camera;
a display coupled to the housing and including a backplane connected to a plurality of chiplets that include an array of micro-LEDs; and
at least one of an infrared emitter configured to project light in the infrared spectrum and a sensor coupled to and in operable communication with at least one of the chiplets, the sensor selected from a group comprising a light sensing module configured to detect light in the visible spectrum, an infrared sensing module configured to detect light in the infrared spectrum, and a temperature sensor configured to detect a temperature proximate the temperature sensor.

2. The rearview mirror assembly according to claim 1, wherein the camera is coupled to the housing and located behind the display and configured to capture image data through the display.

3. The rearview mirror assembly according to claim 2, further including a plurality of the infrared emitters coupled to at least two or more of the plurality of chiplets.

4. The rearview mirror assembly according to claim 3, further including a plurality of the infrared sensing modules, the plurality of the infrared sensing modules located proximate to different ones of the plurality of the infrared emitters.

5. The rearview mirror assembly according to claim 4, wherein each of the plurality of infrared sensing modules is configured to detect increases in the presence of light in the infrared spectrum.

6. The rearview mirror assembly according to claim 5, further including a control system configured to obtain the detected increases in the presence of light in the infrared spectrum from the plurality of infrared sensing modules and generate a user input associated with the region of the detected increases in the presence of light in the infrared spectrum.

7. The rearview mirror assembly according to claim 3, wherein the camera is configured to capture image data of the projected light in the infrared spectrum from the plurality of the infrared emitters.

8. The rearview mirror assembly according to claim 7, further including a control system configured to obtain the image data and detect a position of a vehicle occupant.

9. The rearview mirror assembly according to claim 8, wherein the plurality of infrared emitters are configured to project light in the infrared spectrum in a pattern, and further including a control system configured to extrapolate the position of the vehicle occupant in three-dimensional (“3D”) space based on changes to the pattern.

10. The rearview mirror assembly according to claim 1, further including the light sensing module coupled to at least one of the chiplets and configured to detect light in the visible spectrum.

11. The rearview mirror assembly according to claim 10, further including an electro-optic assembly coupled to the housing and configured to switch transmission states upon an applied voltage.

12. The rearview mirror assembly according to claim 11, further including a control system configured to apply a voltage differential to reduce transmission of the electro-optic assembly based on the detected light from the light sensing module.

13. The rearview mirror assembly according to claim 1, further including the temperature sensor coupled to at least one of the chiplets and configured to detect a temperature proximate the temperature sensor.

14. The rearview mirror assembly according to claim 13, further including a control system configured to reduce power to the display based on the detected temperature and regulate the temperature proximate the temperature sensor.

15. A rearview mirror assembly, comprising:
a housing;
a display coupled to the housing and including a backplane connected to a plurality of chiplets that each include an array of micro-LEDs, the chiplets including internal sensors; and
a control system configured to:
compare data associated with an image requested with data associated with an image produced on the display; and
if the image produced is not substantially the same as the image requested, take a corrective action.

16. The rearview mirror assembly of claim 15, wherein the array of micro-LEDs include red micro-LEDs, green micro-LEDs, and blue micro-LEDs and the control system is configured to compare an intensity of each micro-LEDs to the requested image.

17. The rearview mirror assembly of claim 16, further including a plurality of light sensing modules that detect output of the micro-LEDs and the control system is further configured to compare the output of the micro-LEDs to the requested image.

18. A rearview mirror assembly, comprising:
a housing;
a display coupled to the housing and including a backplane connected to a plurality of chiplets;
an array of micro-LEDs coupled to at least some of the plurality of chiplets; and
at least one of an emitter and a sensor coupled to at least some of the plurality of chiplets.

19. The rearview mirror assembly of claim 18, wherein at least some of the chiplets coupled to the micro-LEDs are also coupled to at least one of the emitter and the sensor.

20. The rearview mirror assembly of claim 18, wherein the chiplets coupled to the micro-LEDs are different than the chiplets coupled to at least one of the emitter and the sensor.
